(19) United States
(12) Patent Application Publication
(10) Pub. No.: US 2009/0145425 A1
(43) Pub. Date: Jun. 11, 2009

(54) Photovoltaic panel and solar-panel unit made using photovoltaic panels of the same sort

(75) Inventors: Giacomo Carcangiu, Genova (IT); Marcello Sardo, Cuneo (IT); Ignazio Carcangiu, Sadali (IT); Rocco Sardo, Cuneo (IT)

Correspondence Address: SEED INTELLECTUAL PROPERTY LAW GROUP PLLC, 701 FIFTH AVE, SUITE 5400, SEATTLE, WA, 98104, US

(73) Assignee: Lasen Development LLC, Wilmington, DE (US)

(21) Appl. No.: 12/001,376

(22) Filed: Dec. 11, 2007

(51) Int. Cl. F24J 2/04; H01L 31/042; H01L 31/058

(52) U.S. Cl. 126/679; 136/244; 136/252

(57) ABSTRACT

A photovoltaic panel has an external casing, which is delimited by at least one wall permeable to light and defines a liquid-tight chamber communicating with the outside world through an inlet passage and an outlet passage; the liquid-tight chamber houses a polydimethylsilicone liquid, which circulates in the liquid-tight chamber itself through the inlet and outlet passages and in which at least one photovoltaic cell is immersed at least partially, electrically connected with the outside of the photovoltaic panel.

The present invention relates to a photovoltaic panel.

### BACKGROUND OF THE INVENTION

In particular, the present invention regards a photovoltaic-cell panel of the type described in the Italian patent No. 01306824, filed on Sep. 30, 1998, and integrally incorporated herein for reasons of completeness of description and as regards the necessary parts.

The photovoltaic panel forming the subject of the aforesaid Italian patent comprises an external liquid-tight casing that is permeable to light, housed in which is a plurality of photovoltaic cells immersed in a fluid.

Following upon exposure of the panel to solar radiation and to the normal activity of photovoltaic cells, the latter convert part of the incident solar energy into electrical energy and accumulate thermal energy by being heated. For the fact of being immersed or embedded in the fluid, the part of heat possessed by the cells is then transferred to the fluid, which, once transferred outside the photovoltaic panel, is sent into a heat exchanger, in this way recovering the heat possessed by the fluid itself.

The mode of implementation described above enables heat-exchanger elements of a “combined” type to be obtained, i.e. ones able to supply simultaneously electrical energy and thermal energy and thus presenting a high yield with respect to traditional heat-exchanger elements that are either only electrical or only thermal.

Experimentally, it has, however, been possible to note that the yield and efficiency of the photovoltaic panels defined above are considerably affected by the type and characteristics of implementation of the fluid used. In fact, fluids with high cooling power, and hence such as to enable an effective and high recovery of the thermal energy, have experimentally proven unsatisfactory from the standpoint of electrical insulation and/or not sufficiently permeable to light or, again, not sufficiently resistant to exposure to solar radiation or to the temperatures reached. Some of the fluids tested have then proven unacceptable from a safety standpoint as regards flammability, environmental pollution, corrosion, and, in general, interaction with the parts of the panel with which the fluid comes into contact.

### SUMMARY OF THE INVENTION

The aim of the present invention is to provide a photovoltaic panel, that will enable a simple and economically advantageous solution to the problems set forth above.

According to the present invention, a photovoltaic element is provided comprising: an external casing, which includes at least one wall permeable to light and delimits a fluid-tight chamber communicating with the outside world through an inlet passage and an outlet passage; a fluid, housed in said chamber and circulating in the chamber itself through said inlet and outlet passages; and a plurality of photovoltaic cells, housed in said chamber and at least partially immersed in said fluid; said photovoltaic element being characterized in that said fluid is a polydimethylsilicone liquid.

### BRIEF DESCRIPTION OF THE DRAWINGS

The invention will now be described with reference to the annexed plates of drawings, which illustrate a non-limiting example of embodiment thereof and in which:

FIG. 1 is a partial perspective view of a photovoltaic-panel apparatus provided with a plurality of photovoltaic panels made according to the dictates of the present invention;

FIG. 2 is a partial plan view of a detail of FIG. 1; and

FIG. 3 is a section at a markedly enlarged scale according to the line III-III of FIG. 2.

### DETAILED DESCRIPTION OF THE INVENTION

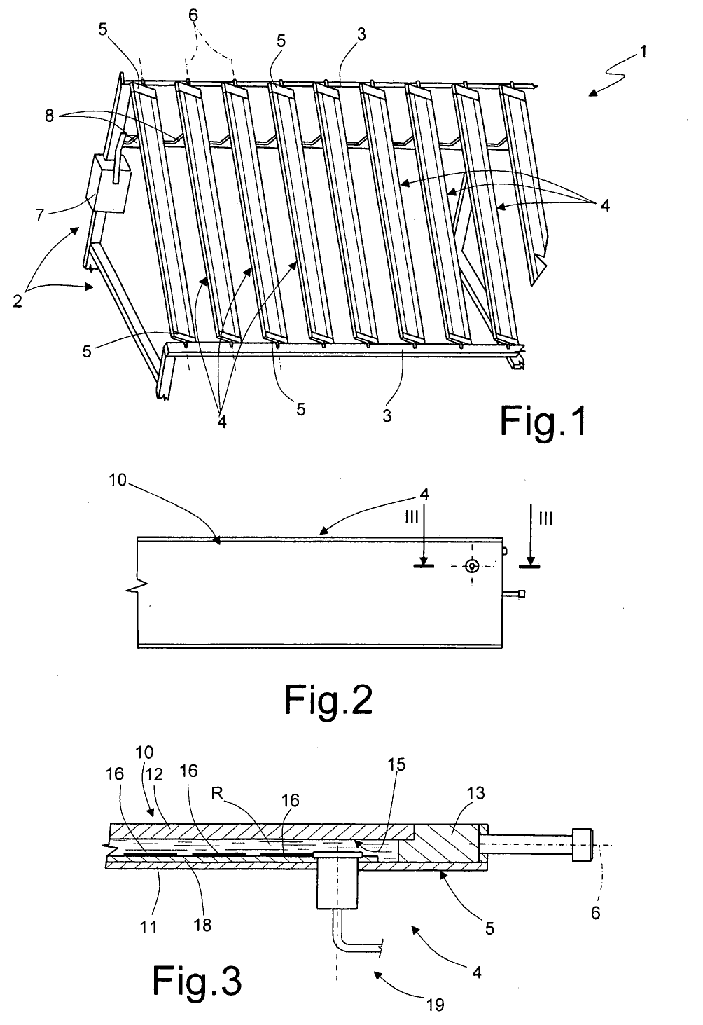

In FIG. 1, designated as a whole by 1, is a solar-panel apparatus, comprising a supporting structure 2, which in turn comprises two cross members 3 and a plurality of photovoltaic solar panels 4 extending orthogonally to the cross members 3 in positions parallel to one another and set alongside one another.

Each panel 4 has respective opposite end longitudinal portions 5, hinged to the respective cross members 3 for turning in opposite directions about a longitudinal fulcrum or hinge axis 6 of its own, parallel to the other longitudinal axes 6. The panels 4 can turn with respect to the structure 2 about the respective hinge axes 6 under the thrust of a single driving motor 7 of a lever transmission 8 coupled to the mobile member of the motor 7, on the one hand, and to each photovoltaic panel 4, on the other.

With explicit reference to FIGS. 2 and 3, each panel 4 comprises a shell or external casing 10, in turn comprising a bottom or rear wall 11, a front wall 12 facing the rear wall 11 and made of a material permeable to light, for example glass, and two terminal closing elements 13.

The front wall 12 and the rear wall 11 and the terminal closing elements 13 delimit between them a fluid-tight chamber 15 communicating with the outside through an inlet passage and an outlet passage, in themselves known and not visible in the attached figures. The fluid-tight chamber 15 houses a plurality of photovoltaic cells 16 (FIG. 3), and a plate 18 for attachment and support of the photovoltaic cells 16 themselves in pre-set positions. The plate 18 is set in contact with the wall 11, and is stably connected to the wall 11 itself. The cells 16 are electrically connected with the outside world through a connector, designated by 19.

In addition to the cells 16, the fluid-tight chamber 15 houses a refrigerating liquid R, which passes in the fluid-tight chamber 15 through the inlet and outlet passages and in which the plate 18 and the photovoltaic cells 16 are at least partially or completely embedded.

The refrigerating liquid R is a silicone liquid and, preferably, a polydimethylsilicone liquid having a viscosity at 25° C. ranging between 40 and 60 mm²/s, a thermal conductivity ranging between 0.10 and 0.20 W|(mk), a flammability point higher than 300° C., and a temperature of combustion ranging between 350° C. and 400° C.

Preferably, moreover, the refrigerating liquid R has a volume resistivity at 25° C. equal to 1.0×1014 Ω·cm.

Conveniently, the liquid used is known by the commercial name “DOW CORNING® 561”. Polydimethylsilicone liquids and, in particular, the liquid commercially known as “DOW CORNING® 561” bestow upon the photovoltaic panel described a yield and efficiency that are far higher than those of known panels, above all owing to the fact that said liquids are associated to a crystalline appearance and hence to a high permeability to light, good properties of electrical insulation in a particularly wide range of temperatures, as well as a high thermal stability. Likewise, polydimethylsilicone liquids and, in particular, the liquid bearing the brand name “DOW CORNING® 561” have a high resistance to exposure of solar radiation over time, and excellent convection capacity, are neither pollutant nor toxic, and are hence safe for human beings, animals and the environment in the case where, for different reasons, they were to be dispersed in the external environment or inhaled, and above all they prove to be non-aggressive or corrosive materials in regard to the other components operating in strict contact with them and/or forming part of the panel, for example plastic and elastomeric materials used with function of seal or gasket, or in regard to the materials constituting parts of connectors and electrical wiring. Said constituent materials of the panel can then be chosen without any limitations according to the conditions of application and on the basis of the effective thermal and mechanical resistance required, without any need to be oversized.

Finally, polydimethylsilicone liquids, in addition to enabling a high overall yield of the panel to be obtained, above all as a result of the effective activity of cooling of the photovoltaic cells, enable an increase in the efficiency of the photovoltaic cells themselves, drastically reducing the amount of microfractures that are generated in the cells on account of the thermal gradients to which the cells are subjected.

As regards, instead, the solar-panel apparatus, it is evident that the fact of being able to orient the panels enables optimal exploitation of solar energy, using, however, constructively simple actuation components and devices having contained costs.

From the foregoing, it appears evident that modifications and variations can be made to the unit 1 and to the panels 4 described herein, without thereby departing from the scope of protection defined by the claims.

In particular, it is evident that the panels and the supporting structure could be obtained in a different way from the one indicated by way of example, for instance to increase the surface exposed to solar radiation, as likewise it is evident that cooling liquids could be used different from the ones indicated herein by way of example, but with chemico-physical characteristics that are comparable with the ones indicated.

1. A photovoltaic element comprising an external casing, which includes at least one wall permeable to light and delimits a fluid-tight chamber communicating with the outside through an inlet passage and an outlet passage; a fluid, housed in said fluid-tight chamber and circulating in the fluid-tight chamber itself through said inlet and outlet passages; and at least one photovoltaic cell, housed in said fluid-tight chamber and at least partially immersed in said fluid; said photovoltaic element being characterized in that said fluid is a polydimethylsilicone liquid.

2. The element according to claim 1, characterized in that said liquid has a viscosity at 25° C. ranging between 40 and 60 mm²/s.

3. The element according to claim 1, characterized in that said liquid has a thermal conductivity ranging between 0.10 and 0.20 W|(mk).

4. The element according to claim 1, characterized in that said liquid has a flammability point higher than 300° C.

5. The element according to claim 1, characterized in that said liquid has a volume resistivity at 25° C. substantially equal to 1.0×1014 Ω·cm.

6. A solar-panel apparatus comprising a supporting structure and a plurality of solar panels set alongside one another; each said panel being built according to claim 1.

7. The apparatus according to claim 6, characterized in that it comprises hinge means set between said supporting structure and each said panel to enable rotation of the panel itself with respect to the structure about a fixed longitudinal hinge axis.

8. The apparatus according to claim 7, characterized in that it comprises motor-driven actuator means for turning said panels each about the corresponding said longitudinal axis.

9. Use of a polydimethylsilicone liquid in an internal chamber of a photovoltaic element comprising at least one photovoltaic cell housed in said chamber and at least partially immersed in said liquid.
